(19) United States
(12) Patent Application Publication
(10) Pub. No.: US 2007/0080415 A1
(43) Pub. Date: Apr. 12, 2007

(54) Complementary metal oxide semicoductor image sensor and method of fabricating the same

(75) Inventor: Eun Sang Cho, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/545,463

(22) Filed: Oct. 11, 2006

(30) Foreign Application Priority Data
Oct. 11, 2005 (KR) 10-2005-0095422

(51) Int. Cl. H01L 31/0232

(52) U.S. Cl. 257/432; 257/E33.068

(57) ABSTRACT

The CMOS image sensor includes one or more photodiodes formed on a semiconductor substrate to generate current in accordance with the amount of incident light, an interlayer insulating layer formed on the semiconductor substrate including the photodiodes, color filter layers formed on the interlayer insulating layer to transmit specific wavelengths, and micro-lenses formed on the color filter layers between the insulating layer patterns to concentrate light on the photodiodes.

### FIELD OF THE INVENTION

The present invention relates to an image sensor and a method of fabricating the same, and more particularly, to a complementary metal oxide semiconductor (CMOS) image sensor capable of improving process stability and a method of fabricating the same.

### BACKGROUND OF THE INVENTION

In general, image sensors are semiconductor devices for converting an optical image into an electrical signal and are categorized into charge coupled device (CCD) image sensor elements and complementary metal oxide semiconductor (CMOS) image sensor elements.

The CMOS image sensor is composed of a photodiode unit for sensing irradiated light and a CMOS logic circuit unit for processing the sensed light into an electrical signal to generate data. As the photodiode receives more light, the photo sensitivity characteristic of the image sensor is improved.

One technology that is used to improve the photo sensitivity of the CMOS image sensor is to increase the fill factor of the photodiode, i.e., the percentage of the area of the photodiode within the image sensor. Another technology is to change the optical path incident to the region outside the photodiode so that all the light is concentrated onto the photodiode.

A typical example of light concentration technology is a micro-lens, in which a convex micro-lens is commonly formed on the photodiode with a material having excellent light transmittance to create the micro-lens, to refract the path of the incident light, and to radiate a larger amount of light onto the photodiode region.

In this case, light parallel to the optical axis of the micro-lens is refracted by the micro-lens so that the focus of the light is formed at a certain location on the optical axis.

A typical CMOS image sensor is composed of a photodiode, an interlayer insulating layer, a color filter, and a micro-lens.

The photodiode senses light incident thereon and converts the sensed light into an electrical signal. The interlayer insulating layer insulates metal wiring lines from each other. The color filter expresses the three primary colors of light, red, green and blue (RGB). The micro-lens concentrates light onto the photodiode.

The least-standardized process among the above-mentioned processes is the process of fabricating the micro-lens.

The micro-lens is formed of a transparent and gentle oval-shaped photo-resist material.

In the current semiconductor fabricating technology, the micro-lens is fabricated by exposing and developing photo-resist by a typical method, and reflowing the photo-resist to thereby form an oval-shaped micro-lens.

Also, in order to improve sensitivity of the CMOS image sensor, the distance between the photodiode and the micro-lens in the CMOS image sensor should be minimized.

On the other hand, reducing the distance between the micro-lens and the photodiode can be achieved either (1) by making a planarization layer very thin or by removing such layer, (2) by reducing the thickness of the interlayer insulating layer, or (3) by controlling the focal length of the micro-lens in accordance with the final thickness of the interlayer insulating layer. One thing to consider is that the concentration degree of light is higher when the focal length of the micro-lens is longer than when the focal length of the micro-lens is shorter.

Therefore, (4) the micro-lens must be designed to be flat. The above four conditions must be considered.

Hereinafter, the conventional CMOS image sensor and the method of fabricating the same will be described with reference to the attached drawings.

FIG. 1 is a cross-sectional view illustrating the conventional CMOS image sensor.

As illustrated in FIG. 1, the conventional CMOS image sensor includes one or more photodiode regions 31 formed on a semiconductor substrate (not shown) to generate charge in accordance with the amount of incident light, an interlayer insulating layer 32 formed on the entire surface including the photodiode 31 regions, a protective layer 33 formed on the interlayer insulating layer 32, R, G, and B color filter layers 34 formed on the protective layer 33 to transmit light components of specific wavelengths, a planarization layer 35 formed on the color filter layers 34, and convex micro-lenses 36 formed on the planarization layer 35 with predetermined curvatures so as to concentrate light that passes through the corresponding color filter layers 34 onto the photodiode 31 regions.

Although not shown in the drawing, an optical shielding layer for preventing light from being incident on the portions outside the photodiode 31 regions is formed in the interlayer insulating layer 32.

Instead of the photodiode, a photo gate may also be used as a light-sensing element.

The curvature and height of the micro-lenses 36 are determined in consideration of various factors such as the location of the focus of the concentrated light. The micro-lenses 36 are mainly made of a polymer-based resin through the processes of patterning by deposition, exposure, development and reflow.

FIGS. 2A to 2C are cross-sectional views illustrating a method of fabricating the conventional CMOS image sensor.

As illustrated in FIG. 2A, the interlayer insulating layer 32 is formed on the semiconductor substrate where a plurality of photo sensing elements such as the photodiodes 31 are formed.

The interlayer insulating layer 32 may be multiple layers. Although not shown, the optical shielding layer for preventing light from being incident on the portions outside the photodiode 31 regions may be formed after one interlayer insulating layer is formed and before another interlayer insulating layer 32 will be formed.

Thereafter, the planarized protective layer 33 for protecting an element from moisture and scratching is formed on the interlayer insulating layer 32.

After the protective layer 33 is coated with a tingible resist layer, exposure and development processes are performed to form the color filter layers 34 for filtering the light components of the respective wavelengths.

In this case, in order to form the color filter layers 34, a mask defined with patterns so that concavo-convex portions can be formed on the boundaries of the color filter layers 34 is used as a photo mask (not shown) used for the exposure process in order to form the color filter layers 34.

Thereafter, the planarized planarization layer 35 is formed on the color filter layers 34 in order to secure planarity for controlling a focus distance and for forming a lens layer.

As illustrated in FIG. 2B, after coating the planarization layer 35 with a resist layer for forming the micro-lenses, the resist layer is patterned by the exposure and development processes to form trapezoidal micro-patterns 36a.

As illustrated in FIG. 2C, the micro-lens patterns 36a are re-flown at between 150 and 200° C. to form the micro-lenses 36.

However, since the reflow process is difficult to standardize and the photo-resist used to form the micro-lenses is very sensitive during the process, it is very difficult to improve the process stability.

Also, the micro-lenses formed on the uppermost layer are exposed to the air.

When the light concentrated by the micro-lenses passes through the color filters and the interlayer insulating layer to reach the photodiode, the light is converted into an electrical signal that is to be displayed. At this time, the length of the micro-lenses, the size and distribution of the color filters, the thickness of the interlayer insulating layer, and the pitch size of the photodiode must be changed in association with each other. The length of the micro-lenses varies heavily and is difficult to be standardized.

Therefore, it is necessary to standardize the shape of the micro-lenses. It is very difficult to measure the shape of the micro-lenses with common measuring devices (optics and CDSEM) in a production line and it may accordingly be meaningless to set a specification in many cases.

### SUMMARY OF THE INVENTION

It is, therefore, an object of the present invention to provide a complementary metal oxide semiconductor (CMOS) image sensor capable of securing process stability and of improving sensitivity to improve the characteristics of the image sensor and a method of fabricating the same.

In accordance with a preferred embodiment of the present invention, there is provided a complementary metal oxide semiconductor (CMOS) image sensor, including one or more photodiodes formed on a semiconductor substrate to generate current in accordance with the amount of incident light, an interlayer insulating layer formed on the entire surface of the semiconductor substrate including the photodiodes, color filter layers formed on the interlayer insulating layer to transmit specific wavelengths, respectively, and micro-lenses formed on the color filter layers between the insulating layer patterns to concentrate light on the photodiodes.

In accordance with another preferred embodiment of the present invention, there is provided a method of fabricating a CMOS image sensor, the method including the steps of forming an interlayer insulating layer on a semiconductor substrate where a plurality of photodiodes are formed, forming color filter layers corresponding to the photodiodes on the interlayer insulating layer, forming insulating layer patterns at the portions that contact the adjacent color filter layers with a uniform distance, and forming flat micro-lenses on the color filter layers between the insulating layer pattern.

In the CMOS image sensor according to the present invention, the micro-lenses and the planarization layer must be formed of films having different refractive indices so that the refractive index of the micro-lenses must be smaller than the refractive index of the planarization layer. According to the law of Snell about the refractive index, in order to increase the focal length and to improve the effect of light concentration, according as the difference in the refractive index between the micro-lenses and the planarization layer increases, the effect of the light concentration is improved.

Also, the planarization layer or the protective layer may be omitted to prevent the concentrated light from being absorbed and to thus reduce the loss of the concentrated light.

### BRIEF DESCRIPTION OF THE DRAWINGS

The above and other objects and features of the present invention will become apparent from the following description of preferred embodiments given in conjunction with the accompanying drawings, in which:

FIG. 1 is a cross-sectional view illustrating a conventional complementary metal oxide semiconductor (CMOS) image sensor;

FIGS. 2A to 2C are cross-sectional views illustrating a method of fabricating the conventional CMOS image sensor.

FIG. 3 is a cross-sectional view illustrating a CMOS image sensor according to the present invention; and

FIGS. 4A to 4C are cross-sectional views illustrating processes of a method of fabricating the CMOS image sensor according to the present invention.

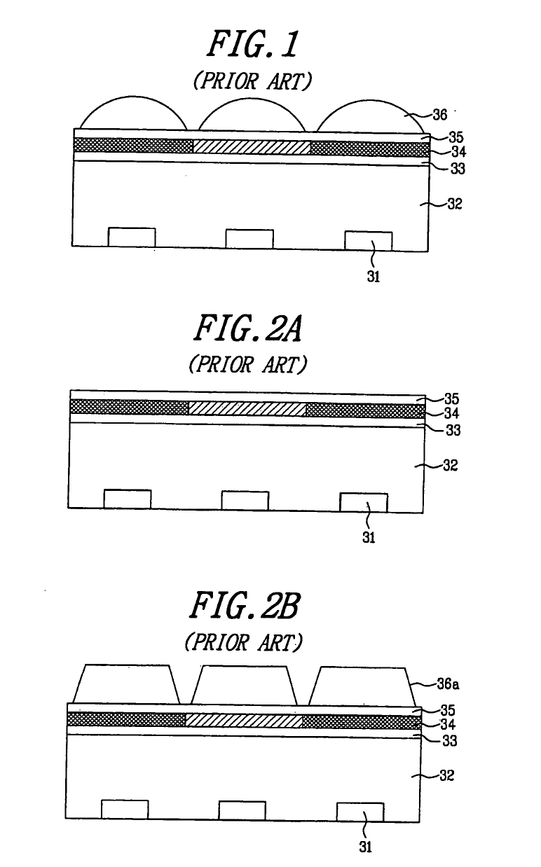

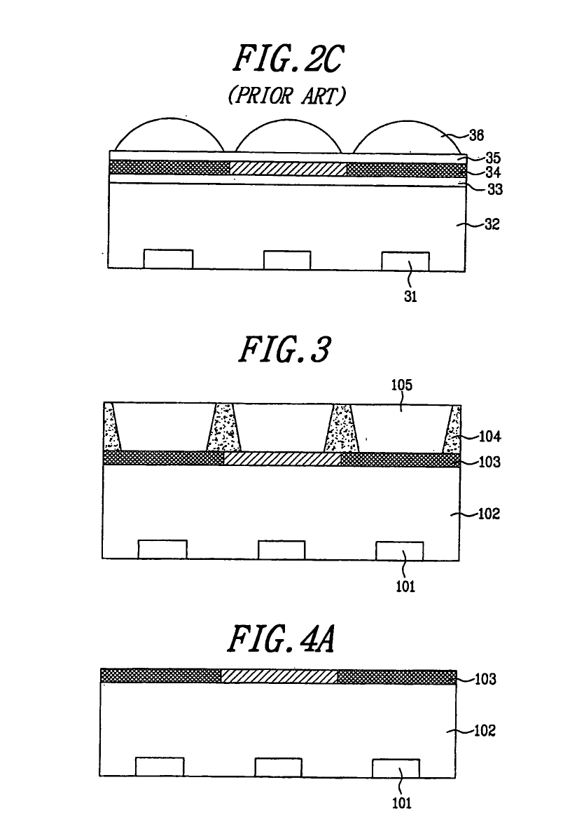

### DETAILED DESCRIPTION OF THE PREFERRED EMBODIMENTS

Hereinafter, preferred embodiments of the present invention will be described in detail with reference to the accompanying drawings so that they can be readily implemented by those skilled in the art.

FIG. 3 is a cross-sectional view illustrating a complementary metal oxide semiconductor (CMOS) image sensor according to the present invention.

As illustrated in FIG. 3, the CMOS image sensor includes one or more photodiodes 101 formed on a semiconductor substrate (not shown) to generate current in accordance with the amount of incident light, an interlayer insulating layer 102 formed on the entire surface including the photodiodes 101, RGB color filter layers 103 formed on the interlayer insulating layer 102 to transmit light components of specific wavelengths, insulating layer patterns 104 formed on the color filter layers 103, and micro-lenses 105 formed on the color filter layers 103 between the insulating layer patterns 104 to concentrate light on the photodiodes 101.

In this case, the insulating layer patterns 104 are formed of Si₃N₄ and the micro-lenses 105 have a flat structure that has the same height as the top surface of the insulating layer patterns 104.

Also, the micro-lenses 105 are formed of a photo-resist or an insulating material that transmits light.

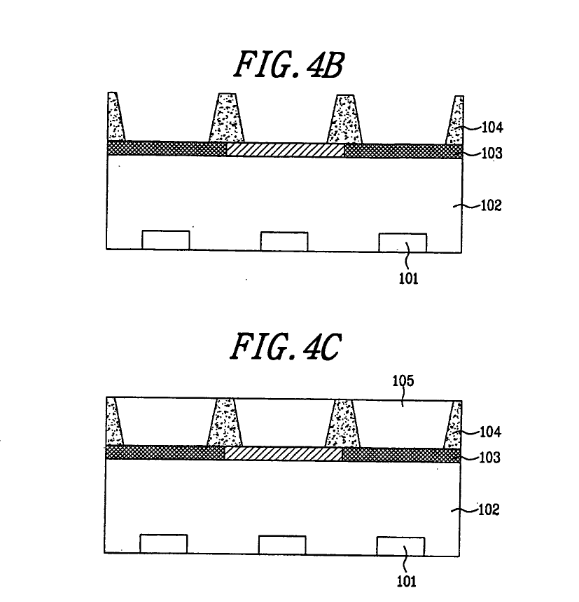

FIGS. 4A to 4C are cross-sectional views illustrating processes of a method of fabricating the CMOS image sensor according to the present invention.

As illustrated in FIG. 4A, the interlayer insulating layer 102 is formed on the semiconductor substrate where a plurality of photo sensing elements such as photodiodes 101 are formed.

In this case, the interlayer insulating layer 102 can be multiple layers. Although not shown, the optical shielding layer for preventing light from being incident on the portions outside the photodiode 101 regions may be formed after one interlayer insulating layer is formed and before another interlayer insulating layer is formed.

Thereafter, the interlayer insulating layer 102 is coated with a tingible resist layer. Thereafter, exposure and development processes are performed to form the RGB color filter layers 103 for filtering the respective wavelengths of the light.

As illustrated in FIG. 4B, an upper insulating layer such as Si₃N₄ is formed on the entire surface including the color filter layers 103. the upper insulating layer is selectively patterned through photolithography and etching processes so that the upper insulating layer is left only at the borders of adjacent color filter layers 103 to form the insulating layer patterns 104.

In this case, the upper insulating layer may be formed of a material that functions as an optical shielding layer in order to prevent light from being incident on the regions outside the photodiode 101 regions.

As illustrated in FIG. 4C, a micro-lens material layer is deposited on the entire surface of the semiconductor substrate including the insulating layer patterns 104 and a planarization process is performed on the entire surface of the micro-lens material layer using the top surface of the insulating patterns 104 as an end point to form the flat micro-lenses 105 on the color filter layers 103 between the insulating layer patterns 104.

In this case, the micro-lens material layer is formed of a photo-resist or an insulating material that transmits light.

On the other hand, parylene (poly-para-xylene) may be used as the insulating material. Parylene is a polymer material that is chain-shaped so that CH₂ is connected to both ends of a benzene ring. Parylene may be categorized as parylene N, parylene C, and parylene D in accordance with the presence of chlorine atoms, the number of chlorine atoms, and the positions where the chlorine atoms are attached. Electrical characteristics such as light transmittance, dielectric constant, and dielectric breakdown strength vary with each type.

While the invention has been shown and described with respect to the preferred embodiments, it will be understood by those skilled in the art that various changes and modifications may be made without departing from the spirit and scope of the invention as defined in the following claims.

The above-described method of fabricating the CMOS image sensor according to the present invention has the following effects.

First, since the insulating layer patterns having a uniform distance are formed and then micro-lenses are planarized to be formed between the insulating layer pattern, the optical path is easily defined and process stability is improved.

Second, it is possible to omit the protective layer and the planarization layer so that the distance between the micro-lenses and the photodiodes may be reduced. As a result, it is possible to improve the sensitivity and the characteristics of the image sensor.

What is claimed is:

1. A complementary metal oxide semiconductor (CMOS) image sensor, comprising:
one or more photodiodes formed on a semiconductor substrate to generate current in accordance with the amount of incident light;
one or more interlayer insulating layers formed on the surface of the semiconductor substrate and the photodiodes;
color filter layers formed on the interlayer insulating layers to transmit specific wavelengths; and
micro-lenses formed on the color filter layers between insulating layer patterns to concentrate light on the photodiodes.

2. The CMOS image sensor of claim 1, wherein the insulating layer patterns are formed of Si₃N₄.

3. The CMOS image sensor of claim 1, wherein the micro-lenses have a flat surface that has the same height as the top surface of the insulating layer pattern.

4. The CMOS image sensor of claim 1, wherein the insulating layer patterns are formed at the borders of adjacent color filter layers.

5. The CMOS image sensor of claim 1, wherein the micro-lenses are formed of a photo-resist or an insulating layer that transmits light.

6. The CMOS image sensor of claim 1, wherein the color filter layers are formed by first coating the interlayer insulating layer with a tingible resist layer, then performing exposure and development processes on the tingible resist layer to form the color filter layers.

7. A method of fabricating a CMOS image sensor, the method comprising the steps of:
forming one or more interlayer insulating layers on a semiconductor substrate on which a plurality of photodiodes are formed;
forming color filter layers on the interlayer insulating layer, each color filter layer corresponding to one of the photodiodes;
forming insulating layer patterns at the borders of adjacent color filter layers; and
forming flat micro-lenses on the color filter layers between the insulating layer patterns.

8. The method of claim 6 wherein, to form the insulating layer patterns, Si₃N₄ is formed on the color filter layers, then the Si₃N₄ is selectively patterned through photolithography and etching processes so that Si₃N₄ remains only at the borders of adjacent color filter layers.

9. The method of claim 6 wherein, to form the flat micro-lenses, a micro-lens material layer is deposited on the color filter layers and the insulating layer patterns, then a planarization process is performed on the micro-lens material layer using the top surface of the insulating patterns as an end point to form the micro-lenses.

10. The method of claim 6, wherein the micro-lenses are formed of a photo-resist or an insulating layer that transmits light.

11. The CMOS image sensor of claim 1, wherein the one or more interlayer insulating layers include a material that functions as an optical shielding layer to prevent light from passing through the one or more interlayer insulating layers.

12. The method of claim 6, wherein the one or more interlayer insulating layers include a material that functions as an optical shielding layer to prevent light from passing through the one or more interlayer insulating layers.

13. The method of claim 6, wherein the color filter layers are formed by first coating the interlayer insulating layer with a tingible resist layer, then performing exposure and development processes on the tingible resist layer to form the color filter layers.
